(19) United States
(12) Patent Application Publication
(10) Pub. No.: US 2026/0033284 A1
(43) Pub. Date: Jan. 29, 2026

(54) SUBSTRATE PROCESSING APPARATUS

(71) Applicant: SCREEN Holdings Co., Ltd., Kyoto (JP)

(72) Inventor: Hitoshi NAKAI, Kyoto-shi (JP)

(21) Appl. No.: 19/229,544

(22) Filed: Jun. 5, 2025

(30) Foreign Application Priority Data
Jul. 29, 2024 (JP) 2024-122047

(51) Int. Cl. H01L 21/677; H01L 21/67

(52) U.S. Cl. CPC H01L 21/67745; H01L 21/67034; H01L 21/67057; H01L 21/67751

(57) ABSTRACT

A substrate processing apparatus includes a first substrate processing portion and a transfer mechanism. The first substrate processing portion processes substrates one by one by immersing each of the substrates in a vertical posture in a first processing liquid. The transfer mechanism receives the substrate in a horizontal posture, changes a posture of the substrate from the horizontal posture to the vertical posture, and carries the substrate in the vertical posture into the first substrate processing portion. The first substrate processing portion includes a processing bath and a substrate placement mechanism. The processing bath has a capacity corresponding to a single substrate. In the processing bath, only the single substrate in the vertical posture is disposed and the first processing liquid is stored. The substrate placement mechanism receives the substrate from the transfer mechanism and places only the single substrate in the vertical posture in the first processing liquid.

### CROSS REFERENCE TO RELATED APPLICATIONS

This application claims the benefit of priority to Japanese Patent Application No. 2024-122047 filed on Jul. 29, 2024. The entire contents of this application are hereby incorporated herein by reference.

### BACKGROUND OF THE INVENTION

### 1. Field of the Invention

The present invention relates to a substrate processing apparatus.

### 2. Description of Related Art

A substrate processing apparatus described in JP 2008-218906 A includes a processing unit, a processing bath, and a transfer device. The processing unit processes one substrate. The processing bath can simultaneously accommodate a plurality of substrates. The processing bath stores a processing liquid in which the substrates are immersed and which processes the substrates. The transfer device can simultaneously transfer substrates the number of which is less than the number of substrates that can be accommodated in the processing bath. The transfer device can receive the substrate from the processing bath and the processing unit. In addition, the transfer device can deliver the substrate to the processing bath and the processing unit.

However, in the substrate processing apparatus described in JP 2008-218906 A, since the processing bath simultaneously processes a plurality of substrates, particles could move between the substrates that are being processed in the processing bath.

One of objects of the present invention is to provide a substrate processing apparatus capable of preventing transfer of particles between substrates during processing.

### SUMMARY OF THE INVENTION

According to one aspect of the present invention, a substrate processing apparatus includes a first substrate processing portion and a transfer mechanism. The first substrate processing portion processes substrates one by one by immersing each of the substrates in a vertical posture in a first processing liquid. The transfer mechanism receives the substrate in a horizontal posture, changes a posture of the substrate from the horizontal posture to the vertical posture, and carries the substrate in the vertical posture into the first substrate processing portion. The first substrate processing portion includes a processing bath and a substrate placement mechanism. The processing bath has a capacity corresponding to a single substrate. In the processing bath, only the single substrate in the vertical posture is disposed and the first processing liquid is stored. The substrate placement mechanism receives the single substrate from the transfer mechanism and places only the single substrate in the vertical posture in the first processing liquid.

In one aspect of the present invention, preferably, the first substrate processing portion further includes a chamber and a drying portion. The chamber accommodates the processing bath. Preferably, the drying portion dries the substrate raised from the processing bath in the chamber.

In one aspect of the present invention, preferably, the substrate processing apparatus includes a plurality of the first substrate processing portions. Preferably, the plurality of first substrate processing portions are disposed along a first direction substantially parallel to a horizontal direction. Preferably, the transfer mechanism carries the substrate in the vertical posture into each of the plurality of first substrate processing portions by moving on a transfer passage extending along the first direction.

In one aspect of the present invention, preferably, the substrate processing apparatus further includes a plurality of second substrate processing portions. Preferably, the plurality of second substrate processing portions are disposed along the first direction. Preferably, each of the plurality of second substrate processing portions processes the substrates one by one by discharging a second processing liquid to the rotating substrate in the horizontal posture. Preferably, the transfer mechanism carries the substrate in the horizontal posture into each of the plurality of second substrate processing portions by moving on the transfer passage. Preferably, the plurality of first substrate processing portions are disposed on one side of the transfer passage in a second direction. Preferably, the plurality of second substrate processing portions are disposed on the other side of the transfer passage in the second direction. Preferably, the second direction is substantially orthogonal to the first direction.

In one aspect of the present invention, preferably, the substrate processing apparatus further includes a controller. Preferably, the controller controls the transfer mechanism, the first substrate processing portion, and the second substrate processing portion. Preferably, the controller causes the transfer mechanism to transfer the substrate such that one or more of the first substrate processing portions and one or more of the second substrate processing portions execute a plurality of processes having order in accordance with the order.

In one aspect of the present invention, preferably, the substrate processing apparatus further includes a second substrate processing portion and a controller. Preferably, the second substrate processing portion processes the substrates one by one by discharging a second processing liquid to the rotating substrate in the horizontal posture. Preferably, the controller controls the transfer mechanism. Preferably, the controller controls the transfer mechanism such that the substrate for which a processing time exceeding a specified time is set is carried into the first substrate processing portion. Preferably, the controller controls the transfer mechanism such that the substrate for which a processing time shorter than or equal to the specified time is set is carried into the second substrate processing portion.

According to at least one aspect of the present invention, transfer of particles between substrates during processing can be prevented.

### BRIEF DESCRIPTION OF THE DRAWINGS

FIG. 1 is a plan view illustrating a substrate processing apparatus according to a preferred embodiment of the present invention.

FIG. 2 is a schematic cross-sectional view illustrating a first substrate processing portion of the substrate processing apparatus according to the present preferred embodiment.

FIG. 3 is a side view illustrating a raising/lowering portion of the first substrate processing portion according to the present preferred embodiment.

FIG. 4 is a view illustrating a processing liquid supplying unit of the substrate processing apparatus according to the present preferred embodiment.

FIG. 5 is a schematic cross-sectional view illustrating a second substrate processing portion of the substrate processing apparatus according to the present preferred embodiment.

FIG. 6A is a side view illustrating a state in which a transfer mechanism of the substrate processing apparatus according to the present preferred embodiment holds a substrate in a horizontal posture.

FIG. 6B is a plan view illustrating the state in which the transfer mechanism holds the substrate in the horizontal posture.

FIG. 7A is a side view illustrating a state in which the transfer mechanism of the substrate processing apparatus according to the present preferred embodiment holds the substrate in a vertical posture.

FIG. 7B is a plan view illustrating the state in which the transfer mechanism holds the substrate in the vertical posture.

FIG. 8 is a view illustrating a state in which the transfer mechanism of the substrate processing apparatus according to the present preferred embodiment delivers the substrate to the first substrate processing portion.

FIG. 9 is a view illustrating a state in which the transfer mechanism of the substrate processing apparatus according to the present preferred embodiment delivers the substrate to the second substrate processing portion.

FIG. 10 is a view illustrating a first stage (the carry-in of the substrate) of an example of a substrate processing method performed by the substrate processing apparatus according to the present preferred embodiment.

FIG. 11 is a view illustrating a middle stage (immersion of the substrate) of an example of the substrate processing method performed by the substrate processing apparatus according to the present preferred embodiment.

FIG. 12 is a view illustrating a last stage (the carry-out of the substrate) of an example of the substrate processing method performed by the substrate processing apparatus according to the present preferred embodiment.

FIG. 13 is a flowchart illustrating a first stage of another example of the substrate processing method performed by the substrate processing apparatus of the present preferred embodiment.

FIG. 14 is a flowchart illustrating a last stage of another example of the substrate processing method performed by the substrate processing apparatus of the present preferred embodiment.

### DETAILED DESCRIPTION OF PREFERRED EMBODIMENTS

Preferred embodiments of the present invention will be described with reference to the drawings. In the drawings, the same or corresponding portions are denoted by the same reference signs, and the description thereof will not be repeated. In the drawings, an X axis, a Y axis, and a Z axis are appropriately illustrated in order to facilitate understanding. The X axis, the Y axis, and the Z axis are orthogonal to each other, the X axis and the Y axis are parallel to a horizontal direction and the Z axis is parallel to a vertical direction. A “plan view” indicates that an object is viewed from vertically above.

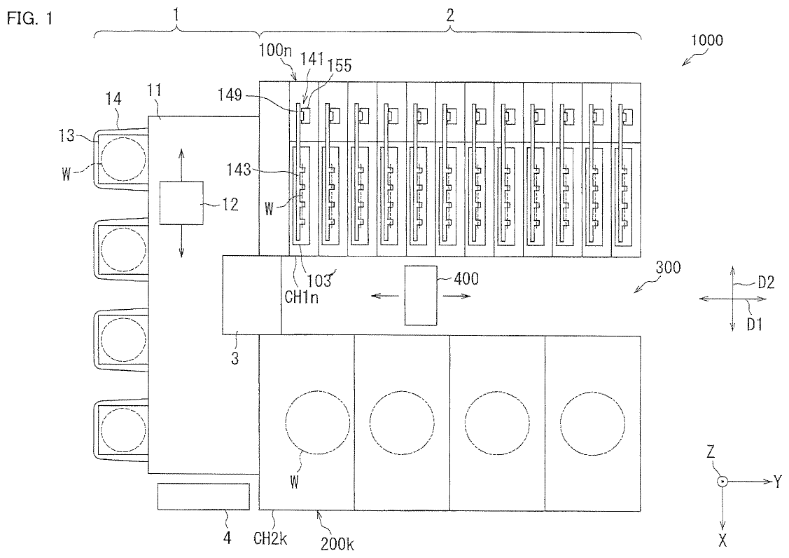

First, a substrate processing apparatus 1000 will be described with reference to FIG. 1. FIG. 1 is a plan view illustrating the substrate processing apparatus 1000 according to a preferred embodiment of the present invention. The substrate processing apparatus 1000 illustrated in FIG. 1 processes a substrate W with a processing liquid.

The substrate W is, for example, a semiconductor wafer, a substrate for a liquid crystal display, a substrate for a plasma display, a substrate for a field emission display (FED), a substrate for an optical disc, a substrate for a magnetic disk, a substrate for a magneto-optical disk, a substrate for a photomask, a ceramic substrate, or a substrate for a solar cell. The semiconductor wafer has, for example, a pattern to form a three-dimensional flash memory (for example, a three-dimensional NAND flash memory). In the following description, as an example, the substrate W is a semiconductor wafer.

The processing liquid is a chemical liquid or a rinse liquid. The chemical liquid includes a chemical liquid diluted with a diluent liquid. The diluent liquid is the same as the rinse liquid.

The chemical liquid is, for example, an etching liquid. The chemical liquid is, for example, dilute hydrofluoric acid (DHF), hydrofluoric acid (HF), nitric hydrofluoric acid (mixed liquid of hydrofluoric acid and nitric acid (HNO₃)), buffered hydrofluoric acid (BHF), ammonium fluoride, HFEG (mixed liquid of hydrofluoric acid and ethylene glycol), phosphoric acid (H₃PO₄), sulfuric acid, acetic acid, nitric acid, hydrochloric acid, ammonia water, hydrogen peroxide water, an organic acid (for example, citric acid, oxalic acid), an organic alkali (for example, TMAH: tetramethylammonium hydroxide), sulfuric acid/hydrogen peroxide water mixture (SPM), ammonia/hydrogen peroxide water mixture (SC1), hydrochloric acid/hydrogen peroxide water mixture (SC2), isopropyl alcohol (IPA), a surfactant, a corrosion inhibitor, or a hydrophobic agent.

The rinse liquid is, for example, deionized water, carbonated water, electrolyzed ion water, hydrogen water, ozone water, or an aqueous hydrochloric acid solution of dilute concentration (for example, approximately 10 ppm to 100 ppm). The rinse liquid is a liquid for washing away the chemical liquid, the byproducts after the processing with the chemical liquid, and/or the foreign matter from the substrate W. The rinse processing is processing of washing away the chemical liquid, the byproducts after the processing with the chemical liquid, and/or the foreign matter from the substrate W.

The substrate processing apparatus 1000 includes an indexer portion 1, a processing portion 2, a substrate mount portion 3, and a controller 4.

The indexer portion 1 includes a transfer portion 11, an indexer robot 12, a plurality of containers 13, and a plurality of container mount tables 14.

The processing portion 2 includes at least one first substrate processing portion 100n and a transfer mechanism 400. In the example of FIG. 1, the processing portion 2 includes a plurality of first substrate processing portions 100n. In the present specification, “n” included in the reference sign indicates an integer of 1 or more. In the example of FIGS. 1, n=1 to 12. The plurality of first substrate processing portions 100n are disposed side by side along a first direction D1. The first direction D1 is substantially parallel to the horizontal direction.

In addition, the processing portion 2 preferably includes at least one second substrate processing portion 200k. In the example of FIG. 1, the processing portion 2 includes a plurality of second substrate processing portions 200k. In the present specification, “k” included in the reference sign indicates an integer of 1 or more. In the example of FIGS. 1, k=1 to 4. The plurality of second substrate processing portions 200k are disposed side by side along the first direction D1.

The processing portion 2 includes a transfer passage 300. The plurality of first substrate processing portions 100n are disposed on one side of the transfer passage 300 in a second direction D2. The plurality of second substrate processing portions 200k are disposed on the other side of the transfer passage 300 in the second direction D2. The second direction D2 is substantially orthogonal to the first direction D1. The second direction D2 is substantially parallel to the horizontal direction.

In the indexer portion 1, the container mount table 14 is connected to the transfer portion 11. The container 13 is mounted on the container mount table 14. The container 13 stores a plurality of substrates W in a horizontal posture.

In the present specification, the horizontal posture of the substrate W indicates a state in which the substrate W is substantially parallel to the horizontal direction. In the horizontal posture of the substrate W, the substrate W may not be strictly horizontal in the horizontal direction.

The indexer robot 12 is disposed in the transfer portion 11. The indexer robot 12 transfers the substrate W in the horizontal posture from the container 13 to the substrate mount portion 3. Further, the indexer robot 12 transfers the substrate W in the horizontal posture from the substrate mount portion 3 to the container 13.

The substrate mount portion 3 includes a mount table on which the substrate W is mounted in the horizontal posture. The substrate mount portion 3 is disposed between the transfer portion 11 and the transfer passage 300. The substrate mount portion 3 is provided to transfer the substrate W between the indexer robot 12 and the transfer mechanism 400.

In the processing portion 2, the first substrate processing portion 100n processes the substrates W one by one by immersing the substrate W in a vertical posture in a first processing liquid. The first processing liquid is an example of the processing liquid described above. Each of the plurality of first substrate processing portions 100n includes a first chamber CH1n, a processing bath 103, and a substrate placement mechanism 141. The substrate placement mechanism 141 includes a substrate holding portion 143, a supporting portion 149, and a raising/lowering portion 155. Details thereof will be described below.

The first chamber CH1n corresponds to an example of a “chamber” of the present invention.

In the present specification, the vertical posture of the substrate W indicates a state in which the substrate W is substantially parallel to the vertical direction. In the vertical posture of the substrate W, the substrate W may not be strictly horizontal in the vertical direction.

In addition, the second substrate processing portion 200k processes the substrates W one by one by discharging a second processing liquid to the rotating substrate W in the horizontal posture. Each of the plurality of second substrate processing portions 200k includes a second chamber CH2k. The second processing liquid is an example of the processing liquid described above.

The transfer passage 300 is disposed between a region in which the plurality of first substrate processing portions 100n are disposed and a region in which the plurality of second substrate processing portions 200k are disposed. The transfer mechanism 400 is disposed on the transfer passage 300. The transfer passage 300 extends along the first direction D1.

The transfer mechanism 400 receives the substrate W in the horizontal posture from the substrate mount portion 3, changes a posture of the substrate W from the horizontal posture to the vertical posture, and carries the substrate W in the vertical posture into the first substrate processing portion 100n.

The transfer mechanism 400 carries out the substrate W in the vertical posture from the first substrate processing portion 100n, changes a posture of the substrate W from the vertical posture to the horizontal posture, and transfers the substrate W in the horizontal posture to the substrate mount portion 3.

The transfer mechanism 400 receives the substrate W in the horizontal posture from the substrate mount portion 3 and carries the substrate W in the horizontal posture into the second substrate processing portion 200k.

The transfer mechanism 400 carries out the substrate W in the horizontal posture from the second substrate processing portion 200k and transfers the substrate W in the horizontal posture to the substrate mount portion 3.

The transfer mechanism 400 carries out the substrate W in the vertical posture from the first substrate processing portion 100n, changes a posture of the substrate W from the vertical posture to the horizontal posture, and carries the substrate W in the horizontal posture into the second substrate processing portion 200k.

The transfer mechanism 400 carries out the substrate W in the horizontal posture from the second substrate processing portion 200k, changes a posture of the substrate W from the horizontal posture to the vertical posture, and carries the substrate W in the vertical posture into the first substrate processing portion 100n.

The transfer mechanism 400 moves in the first direction D1 on the transfer passage 300. The transfer mechanism 400 carries the substrate W in the vertical posture to be processed by the first substrate processing portion 100n into each of the plurality of first substrate processing portions 100n by moving on the transfer passage 300. Therefore, according to the present preferred embodiment, the transfer mechanism 400 can quickly transfer the substrate W from one first substrate processing portion 100n to another first substrate processing portion 100n by moving on the transfer passage 300 in the first direction D1 from one first substrate processing portion 100n to another first substrate processing portion 100n. As a result, it is possible to suppress particles from adhering to the substrate W.

In addition, the transfer mechanism 400 carries the substrate W in the horizontal posture to be processed by the second substrate processing portion 200k into each of the plurality of second substrate processing portions 200k by moving on the transfer passage 300. Therefore, according to the present preferred embodiment, the transfer mechanism 400 can quickly transfer the substrate W from one second substrate processing portion 200k to another second substrate processing portion 200k by moving on the transfer passage 300 in the first direction D1 from one second substrate processing portion 200k to another second substrate processing portion 200k. As a result, it is possible to suppress particles from adhering to the substrate W.

The posture of the substrate W being transferred on the transfer passage 300 is not particularly limited.

The controller 4 controls the indexer robot 12, the first substrate processing portion 100n, the second substrate processing portion 200k, and the transfer mechanism 400. The controller 4 is, for example, a computer. Specifically, the controller 4 includes a processor such as a central processing unit (CPU). The controller 4 further includes a storage. The storage stores data and a computer program. The storage includes, for example, a main storage such as a semiconductor memory and an auxiliary storage such as a semiconductor memory and a hard disk drive. The processor of the controller 4 executes the computer program stored in the storage of the controller 4 to control the indexer robot 12, the first substrate processing portion 100n, the second substrate processing portion 200k, and the transfer mechanism 400.

As described above with reference to FIG. 1, according to the present preferred embodiment, the plurality of first substrate processing portions 100n are disposed on one side of the transfer passage 300 in the second direction D2. The plurality of second substrate processing portions 200k are disposed on the other side of the transfer passage 300 in the second direction D2. Therefore, the transfer mechanism 400 disposed on the transfer passage 300 can quickly carry the substrate W from the first substrate processing portion 100n into the second substrate processing portion 200k. Similarly, the transfer mechanism 400 can quickly carry the substrate W from the second substrate processing portion 200k into the first substrate processing portion 100n. Therefore, it is possible to suppress particles from adhering to the substrate W.

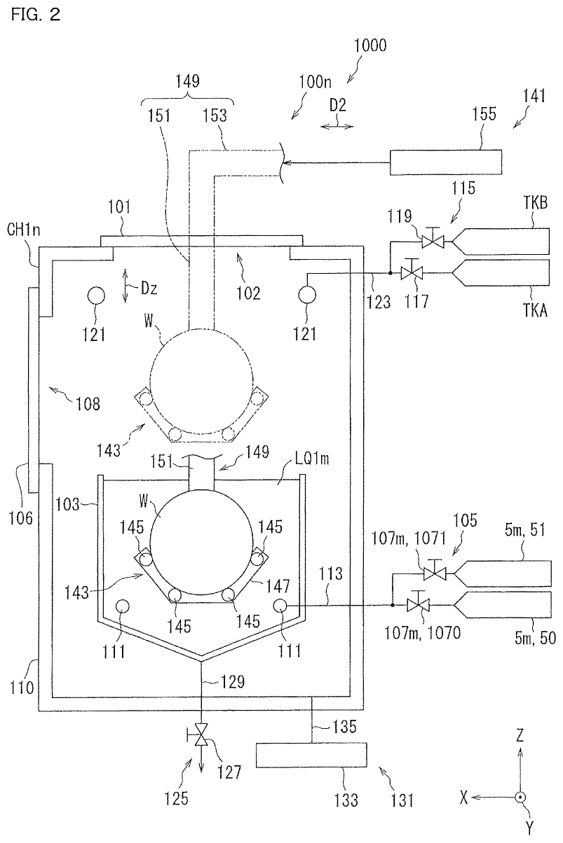

Next, details of the first substrate processing portion 100n will be described with reference to FIG. 2. FIG. 2 is a schematic cross-sectional view illustrating the first substrate processing portion 100n. As illustrated in FIG. 2, the first substrate processing portion 100n includes the first chamber CH1n, the processing bath 103, a processing liquid supplying portion 105, a draining portion 125, and the substrate placement mechanism 141. The first substrate processing portion 100n preferably further includes a drying portion 115. The first substrate processing portion 100n may further include a decompression portion 131. The substrate processing apparatus 1000 includes at least one processing liquid supplying unit 5m. In the example of FIG. 2, the substrate processing apparatus 1000 includes a plurality of processing liquid supplying units 5m. In the present specification, “m” included in the reference sign indicates an integer of 0 or more. In the example of FIG. 2, m=0, 1.

The processing liquid supplying portion 105 includes at least one valve 107m, at least one nozzle 111, and a piping 113. In the example of FIG. 2, the processing liquid supplying portion 105 includes a plurality of valves 107m and a plurality of nozzles 111.

The drying portion 115 includes a valve 117, a valve 119, at least one nozzle 121, and a piping 123. In the example of FIG. 2, the drying portion 115 includes a plurality of nozzles 121.

The draining portion 125 includes a valve 127 and a piping 129. The decompression portion 131 includes an exhaust portion 133 and a piping 135.

The substrate placement mechanism 141 includes a substrate holding portion 143, a supporting portion 149, and a raising/lowering portion 155. The substrate holding portion 143 includes a base portion 147 and a plurality of holding members 145. The supporting portion 149 includes a first supporting portion 151 and a second supporting portion 153.

The first chamber CH1n accommodates the processing bath 103, the substrate holding portion 143, and the nozzles 111 and 121. The first chamber CH1n has, for example, substantially a box shape. The first chamber CH1n includes a cover 101. The cover 101 is disposed in an upper opening 102 of the first chamber CH1n. The cover 101 can be opened and closed.

The first chamber CH1n also includes a side wall 110 and a shutter 106 which are substantially parallel to a vertical direction Dz. The side wall 110 has an opening 108. The opening 108 extends in the vertical direction Dz. The opening 108 (opening edge) has a shape corresponding to the substrate W in the vertical posture. The shutter 106 moves along the vertical direction Dz to block the opening 108 or open the opening 108. That is, the shutter 106 closes or opens the opening 108. For example, the shutter 106 is driven by a drive portion (not illustrated). The drive portion includes, for example, a ball screw mechanism and a motor. The shutter 106 may open or close the opening 108 by moving in the first direction D1 (FIG. 1).

The processing bath 103 stores a first processing liquid LQ1m. The case of “m=0” indicates that the first processing liquid LQ10 is a rinse liquid. The case of “m>0” indicates that the first processing liquid LQ1m is a chemical liquid. In this case, a difference in m indicates a difference in the type of the chemical liquid. The first processing liquid LQ11 is a chemical liquid.

Specifically, the processing bath 103 has a capacity corresponding to one substrate W. In the processing bath 103, only one substrate W in the vertical posture is disposed. Therefore, in the processing bath 103, only one substrate W is processed with the first processing liquid LQ1m. As a result, according to the present preferred embodiment, it is possible to suppress “transfer of particles between the substrates W being processed” which will occur in a case where a plurality of substrates W are collectively processed.

In the present preferred embodiment, the processing bath 103 has a capacity corresponding to one substrate W. Therefore, when the first processing liquid LQ1m is a chemical liquid, the concentration of dissolved oxygen in the first processing liquid LQ1m can be easily reduced and the concentration of dissolved oxygen in the first processing liquid LQ1m can be easily maintained at a low concentration of dissolved oxygen as compared with a case where the processing bath has a large capacity corresponding to the collective processing of a plurality of substrates W. Therefore, it is possible to suppress variations in the processing amount while improving the processing amount (for example, the etching amount) of the substrate W with the first processing liquid LQ1m.

The processing liquid supplying portion 105 supplies the first processing liquid LQ1m to the processing bath 103. Specifically, in the processing liquid supplying portion 105, the plurality of nozzles 111 are disposed inside the processing bath 103. The plurality of nozzles 111 are connected to the piping 113. The valve 107m is disposed in the piping 113. The piping 113 is connected to the processing liquid supplying unit 5m through a valve 107m. The processing liquid supplying unit 5m supplies the first processing liquid LQ1m. Therefore, when the valve 107m is opened, the first processing liquid LQ1m is supplied to the plurality of nozzles 111 through the piping 113. As a result, the plurality of nozzles 111 supplies the first processing liquid LQ1m to the processing bath 103.

In the present preferred embodiment, when one valve 107m of the plurality of valves 107m is opened, the other valves 107m are closed. Therefore, when a valve 1070 is opened, a valve 1071 is closed, and the first processing liquid LQ10 (rinse liquid) from a processing liquid supplying unit 50 is discharged from the nozzle 111 to the processing bath 103. On the other hand, when the valve 1071 is opened, the valve 1070 is closed, and the first processing liquid LQ11 (chemical liquid) from a processing liquid supplying unit 51 is discharged from the nozzle 111 to the processing bath 103.

The drying portion 115 dries the substrate W pulled up from the processing bath 103 in the first chamber CH1n by supplying a fluid into the first chamber CH1n. The fluid is a gas or a liquid. Specifically, in the drying portion 115, the plurality of nozzles 121 are disposed inside the first chamber CH1n and outside the processing bath 103. The plurality of nozzles 121 are connected to the piping 123. The valves 117 and 119 are disposed in the piping 123. The piping 123 is connected to an organic solvent supply source TKA through the valve 117. The piping 123 is connected to an inert gas supply source TKB through the valve 119.

Therefore, when the valve 117 is opened and the valve 119 is closed, vapor of an organic solvent is supplied from the organic solvent supply source TKA to the plurality of nozzles 121 through the piping 123. As a result, the plurality of nozzles 121 supply the vapor of the organic solvent into the first chamber CH1n. In the present specification, the organic solvent is water-soluble and has a smaller surface tension than that of the rinse liquid. For example, the organic solvent is low-carbon monohydric alcohol, ethylene glycol, or lower ketone. The low-carbon monohydric alcohol is, for example, methanol, ethanol, or isopropyl alcohol (IPA). In the present preferred embodiment, the organic solvent is IPA.

On the other hand, when the valve 117 is closed and the valve 119 is opened, an inert gas is supplied from the inert gas supply source TKB to the plurality of nozzles 121 through the piping 123. As a result, the plurality of nozzles 121 supply the inert gas into the first chamber CH1n. In the present specification, the inert gas is nitrogen or argon. In the present preferred embodiment, the inert gas is nitrogen.

As described above with reference to FIG. 2, according to the present preferred embodiment, when the substrate W is immersed in the first processing liquid LQ11 (chemical liquid) that is stored in the processing bath 103, the substrate W is processed with the first processing liquid LQ11. Then, when the substrate W is immersed in the first processing liquid LQ10 (rinse liquid) that is stored in the processing bath 103, the substrate W is cleaned with the first processing liquid LQ10. Further, when the substrate W is pulled up from the processing bath 103, the drying portion 115 dries the substrate W.

Therefore, in the present preferred embodiment, in the first chamber CH1n that accommodates the processing bath 103 to process only one substrate W, not only the processing of the substrate W with the first processing liquid LQ1m but also the drying of the substrate W can be executed. As a result, the transfer mechanism 400 can immediately carry the substrate W processed in the first substrate processing portion 100n into the other first substrate processing portion 100n or the second substrate processing portion 200k. Therefore, the throughput of the processing of the substrate W can be improved.

If the first substrate processing portion 100n does not include the drying portion 115, it is necessary to dry the substrate W outside the first substrate processing portion 100n, and thus, there is a possibility that the throughput of the processing of the substrate W cannot be improved. However, it is a preferable example that the first substrate processing portion 100n includes the drying portion 115, and in the present invention, the first substrate processing portion 100n may not include the drying portion 115.

Subsequently, referring to FIG. 2, the draining portion 125 discharges the first processing liquid LQ1m from the processing bath 103. Specifically, the piping 129 of the draining portion 125 is connected to the bottom portion of the processing bath 103. The valve 127 is disposed in the piping 129. When the valve 127 is opened, the first processing liquid LQ1m in the processing bath 103 is discharged through the piping 129.

The decompression portion 131 reduces the pressure in the first chamber CH1n to a pressure less than the atmospheric pressure. Specifically, the exhaust portion 133 of the decompression portion 131 is connected to the first chamber CH1n through the piping 135. The exhaust portion 133 exhausts the gas in the first chamber CH1n to reduce the pressure in the first chamber CH1n to a pressure less than the atmospheric pressure. The exhaust portion 133 includes, for example, an exhaust pump.

The substrate placement mechanism 141 lowers the substrate W and immerses the substrate W in the first processing liquid LQ1m in the processing bath 103. Specifically, the substrate placement mechanism 141 receives the substrate W in the vertical posture from the transfer mechanism 400 (FIG. 1) and places only one substrate W in the vertical posture in the first processing liquid LQ1m in the processing bath 103. Alternatively, the substrate placement mechanism 141 raises the substrate W and pulls up the substrate W from the first processing liquid LQ1m in the processing bath 103.

That is, the substrate placement mechanism 141 raises or lowers only one substrate W between an inside-bath position and an outside-bath position. The inside-bath position indicates a position where the substrate holding portion 143 is disposed in the processing bath 103. Therefore, when the first processing liquid LQ1m is stored in the processing bath 103, the inside-bath position indicates a position where the substrate W is immersed in the first processing liquid LQ1m in the processing bath 103.

On the other hand, the outside-bath position indicates a position where the substrate holding portion 143 is disposed outside the processing bath 103. That is, the outside-bath position indicates a position where the substrate holding portion 143 is disposed over the processing bath 103. Therefore, when the first processing liquid LQ1m is stored in the processing bath 103, the outside-bath position indicates a position where the substrate W is not in contact with the first processing liquid LQ1m because the substrate W is positioned over the processing bath 103.

More specifically, in the substrate placement mechanism 141, the substrate holding portion 143 holds only one substrate W in the vertical posture. The substrate holding portion 143 includes a base portion 147 and a plurality of holding members 145. The plurality of holding members 145 are fixed to the base portion 147. The plurality of holding members 145 hold only one substrate W in the vertical posture. For example, the plurality of holding members 145 are protrusions protruding from the base portion 147 in the first direction D1 (FIG. 1). The plurality of holding members 145 are disposed at intervals along the peripheral edge of the substrate W and support a part of the peripheral edge of the substrate W from below. The configuration of the substrate holding portion 143 is not particularly limited as long as the substrate holding portion 143 can hold only one substrate W in the vertical posture.

Further, the supporting portion 149 is connected to the substrate holding portion 143. The supporting portion 149 supports the substrate holding portion 143. In the supporting portion 149, the first supporting portion 151 extends in the vertical direction Dz. The first supporting portion 151 is, for example, a substantially columnar or substantially plate-shaped member. A lower end portion of the first supporting portion 151 is connected to the base portion 147. The second supporting portion 153 extends along the second direction D2. One end portion of the second supporting portion 153 in the second direction D2 is connected to an upper end portion of the first supporting portion 151. The other end portion of the second supporting portion 153 in the second direction D2 is connected to the raising/lowering portion 155. The second supporting portion 153 is, for example, a substantially columnar or substantially plate-shaped member.

Further, the raising/lowering portion 155 raises or lowers the substrate holding portion 143 connected to the supporting portion 149 by raising or lowering the supporting portion 149. As a result, one substrate W held by the substrate holding portion 143 moves up or down. Specifically, the raising/lowering portion 155 lowers the substrate holding portion 143 by lowering the supporting portion 149 and immerses one substrate W in the first processing liquid LQ1m in the processing bath 103. As a result, the substrate W is disposed at the inside-bath position. Alternatively, the raising/lowering portion 155 raises the substrate holding portion 143 by raising the supporting portion 149 and pulls up one substrate W from the first processing liquid LQ1m in the processing bath 103. As a result, the substrate W is disposed at the outside-bath position.

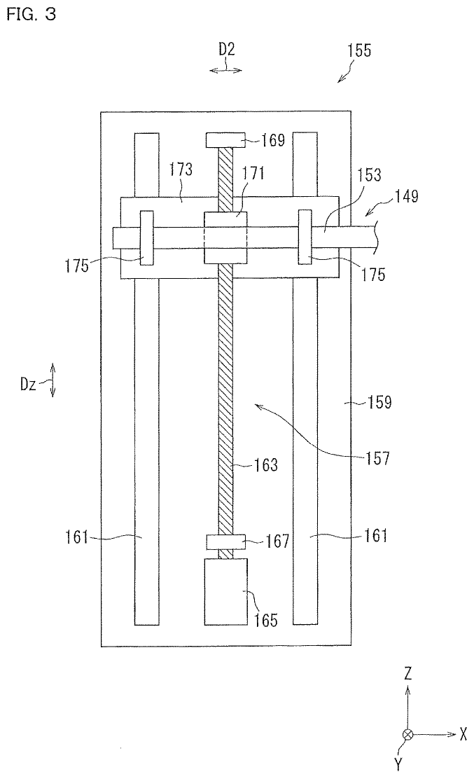

Next, details of the raising/lowering portion 155 will be described with reference to FIG. 3. FIG. 3 is a side view illustrating the raising/lowering portion 155. As illustrated in FIG. 3, the raising/lowering portion 155 includes a ball screw mechanism 157 and a plurality of fixing members 175. The plurality of fixing members 175 fix the supporting portion 149 to the ball screw mechanism 157. Therefore, the ball screw mechanism 157 raises or lowers the substrate holding portion 143 by raising or lowering the supporting portion 149. Specifically, the plurality of fixing members 175 fix the other end portion of one end portion and the other end portion of the second supporting portion 153 in the second direction D2 to the ball screw mechanism 157. The fixing method is not particularly limited as long as the supporting portion 149 is fixed to the ball screw mechanism 157.

Specifically, the ball screw mechanism 157 includes a base 159, a plurality of guide rails 161, a screw shaft 163, a motor 165, a first bearing 167, a second bearing 169, a nut 171, and a slider 173.

A rotating shaft of the motor 165 is connected to the screw shaft 163. The motor 165 rotates the screw shaft 163. The screw shaft 163 extends along the vertical direction Dz. A lower end portion of the screw shaft 163 is supported by the first bearing 167. An upper end portion of the screw shaft 163 is supported by the second bearing 169. The first bearing 167 and the second bearing 169 are fixed to the base 159. The screw shaft 163 is screwed into the nut 171 and passes through the nut 171.

The nut 171 is fixed to the slider 173. The slider 173 is connected to the plurality of guide rails 161 to be slidable along the vertical direction Dz. The plurality of guide rails 161 extend along the vertical direction Dz. The plurality of guide rails 161 are fixed to the base 159.

The plurality of fixing members 175 are fixed to the slider 173. Then, the supporting portion 149 (specifically, the second supporting portion 153) is fixed to the slider 173 by the plurality of fixing members 175.

When the motor 165 rotates, the screw shaft 163 rotates, and the slider 173 moves up or down along the plurality of guide rails 161. As a result, the supporting portion 149 fixed to the slider 173 moves up or down. Therefore, the substrate holding portion 143 (FIG. 2) connected to the supporting portion 149 moves up or down.

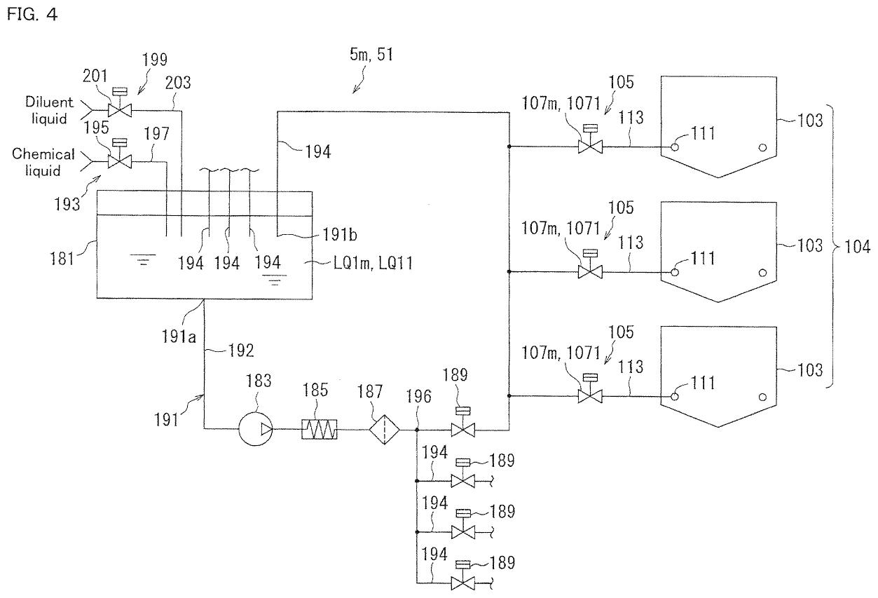

Next, details of the processing liquid supplying unit 51 (FIG. 2) will be described with reference to FIG. 4. FIG. 4 is a view illustrating the processing liquid supplying unit 51. As shown in FIG. 4, the processing liquid supplying unit 51 includes a processing liquid tank 181, a pump 183, a heater 185, a filter 187, a plurality of circulation valves 189, a circulation piping 191, a chemical liquid supplying portion 193, and a diluent liquid supplying portion 199.

An upstream end 191a of the circulation piping 191 is connected to the processing liquid tank 181, and a downstream end 191b of the circulation piping 191 is connected to the processing liquid tank 181.

The first processing liquid LQ11 (chemical liquid) in the processing liquid tank 181 is circulated through the processing liquid tank 181 and the circulation piping 191. The circulation piping 191 commonly supplies the first processing liquid LQ11 to the plurality of processing baths 103. When the pipings 113 provided corresponding to the processing baths 103 are branched from the circulation piping 191, the first processing liquid LQ11 flowing through the circulation piping 191 is supplied to the processing baths 103 through the pipings 113.

Specifically, as an example, the predetermined number of processing baths 103 constitute a processing bath group 104. In the example of FIG. 4, the processing bath group 104 includes three processing baths 103. Since the substrate processing apparatus 1000 illustrated in FIG. 1 has twelve processing baths 103, the substrate processing apparatus 1000 has four processing bath groups 104. Then, the circulation piping 191 supplies the first processing liquid LQ11 to the four processing bath groups 104.

More specifically, the circulation piping 191 includes a common piping 192 extending downstream from the processing liquid tank 181 and a plurality of individual pipings 194 branching from the common piping 192. The plurality of individual pipings 194 branch from the common piping 192 at a branch position 196. An upstream end 192a of the common piping 191 is connected to the processing liquid tank 181. A downstream end 191b of each individual piping 194 is connected to the processing liquid tank 181.

The plurality of individual pipings 194 correspond to the plurality of processing bath groups 104. FIG. 4 illustrates the whole of one individual piping 194 and a part of each of the remaining three individual pipings 194. The one individual piping 194 supplies the first processing liquid LQ11 to each of the processing baths 103 of one processing bath group 104, and the remaining three individual pipings 194 supply the first processing liquid LQ11 to each of the processing baths 103 of the remaining three processing bath groups 104.

The circulation valve 189 is disposed in each individual piping 194. When the circulation valve 189 is opened, the first processing liquid LQ11 circulates through the individual piping 194. Then, the first processing liquid LQ11 is supplied to each of the processing baths 103 of the processing bath group 104 through the plurality of pipings 113 branched from the individual piping 194.

The pump 183 feeds the first processing liquid LQ11 in the processing liquid tank 181 to the circulation piping 191. The heater 185 adjusts the temperature of the first processing liquid LQ11 in the processing liquid tank 181 by heating the first processing liquid LQ11 flowing through the circulation piping 191. The filter 187 captures particles contained in the first processing liquid LQ11 flowing through the circulation piping 191. The pump 183, the heater 185, and the filter 187 are disposed in the circulation piping 191 (specifically, the common piping 192) from upstream to downstream in that order.

Also, the chemical liquid supplying portion 193 supplies the chemical liquid to the processing liquid tank 181. The chemical liquid supplying portion 193 includes a valve 195 and a piping 197. When the valve 195 is opened, the chemical liquid is supplied from the piping 197 to the processing liquid tank 181. The diluent liquid supplying portion 199 supplies the diluent liquid to the processing liquid tank 181. The diluent liquid supplying portion 199 includes a valve 201 and a piping 203. When the valve 201 is opened, the diluent liquid is supplied from the piping 203 to the processing liquid tank 181. As an example, the first processing liquid LQ11 is formed by diluting the chemical liquid with the diluent liquid.

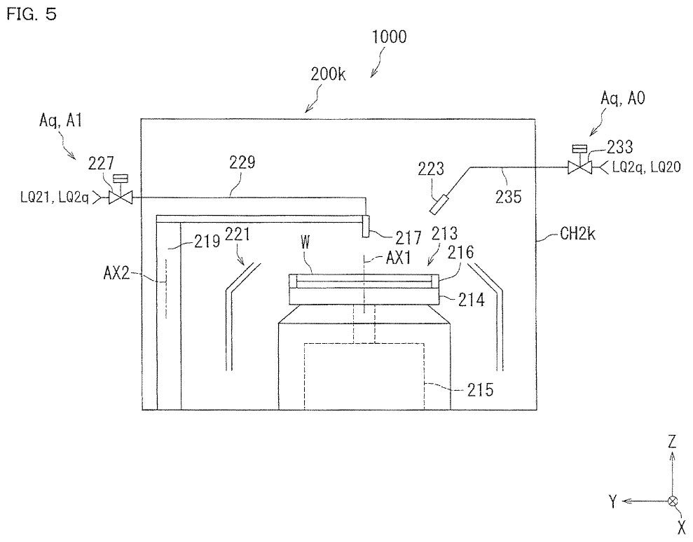

Next, details of the second substrate processing portion 200k will be described with reference to FIG. 5. FIG. 5 is a schematic cross-sectional view illustrating the second substrate processing portion 200k. As illustrated in FIG. 5, the second substrate processing portion 200k includes a second chamber CH2k, a spin chuck 213, a spin motor 215, at least one processing liquid supplying portion Aq, a nozzle moving portion 219, and a plurality of guards 221. In the example of FIG. 5, the second substrate processing portion 200k includes a plurality of processing liquid supplying portions Aq. In the present specification, “q” included in the reference sign indicates an integer of 0 or more. In the example of FIG. 5, q=0, 1.

The processing liquid d supplying portion A0 includes a nozzle 223, a valve 233, and a piping 235. The processing liquid supplying portion A1 includes a nozzle 217, a valve 227, and a piping 229.

The second chamber CH2k has a substantially box shape. The second chamber CH2k accommodates the spin chuck 213, the spin motor 215, the nozzles 217 and 223, the nozzle moving portion 219, and the plurality of guards 221. The valves 227 and 233 may be accommodated in the second chamber CH2k.

The spin chuck 213 holds the substrate W. Specifically, the spin motor 215 rotates the spin chuck 213 around a rotational axis AX1. Therefore, the spin chuck 213 rotates the substrate W around the rotational axis AX1 while horizontally holding the substrate W. Specifically, the spin chuck 213 includes a plurality of chuck members 216 and a spin base 214. The spin base 214 has a substantially disk shape and supports the plurality of chuck members 216 in the horizontal posture. The plurality of chuck members 216 holds the substrate W in the horizontal posture. The spin chuck 213 may be, for example, a vacuum chuck or a Bernoulli chuck using the Bernoulli effect, and is not particularly limited.

The processing liquid supplying portion Aq supplies a second processing liquid LQ2q to the substrate W. The case of “q=0” indicates that the second processing liquid LQ20 is a rinse liquid. The case of “q>0” indicates that the second processing liquid LQ2q is a chemical liquid. In this case, a difference in q indicates a difference in the type of the chemical liquid. The second processing liquid LQ21 is a chemical liquid.

Specifically, the processing liquid supplying portion A1 supplies the second processing liquid LQ21 (chemical liquid) to the substrate W. In the processing liquid supplying portion A1, the nozzle 217 discharges the second processing liquid LQ21 to the substrate W. The nozzle moving portion 219 raises and lowers the nozzle 217 and horizontally rotates the nozzle 217 around a rotational axis AX2. The nozzle moving portion 219 includes, for example, a ball screw mechanism and a motor that applies a driving force to the ball screw mechanism in order to raise and lower the nozzle 217. The nozzle moving portion 219 includes, for example, a motor in order to horizontally turn the nozzle 217.

Specifically, the piping 229 is connected to the nozzle 217. The valve 227 is disposed in the piping 229. The valve 227 opens and closes a flow path of the piping 229 and switches between supply and stop of the second processing liquid LQ21 to the nozzle 217. When the valve 227 opens the flow path of the piping 229, the nozzle 217 discharges the second processing liquid LQ21 to the substrate W.

In addition, the processing liquid supplying portion A0 supplies the second processing liquid LQ20 (rinse liquid) to the substrate W. In the processing liquid supplying portion A0, the nozzle 223 discharges the second processing liquid LQ20 to the substrate W. Specifically, the piping 235 is connected to the nozzle 223. The valve 233 is disposed in the piping 235. The valve 233 opens and closes a flow path of the piping 235 and switches between supply and stop of the second processing liquid LQ20 to the nozzle 223. When the valve 233 opens the flow path of the piping 235, the nozzle 223 discharges the second processing liquid LQ20 to the substrate W.

Each guard 221 has a substantially tubular shape. Each guard 221 receives the second processing liquid LQ2q discharged from the substrate W.

As described above, in the present preferred embodiment described with reference to FIGS. 1 to 5, preferably, in a case where chemical liquid processing for a relatively long time is required, the substrates W are processed in the processing bath 103 of the first substrate processing portion 100n. Therefore, the consumption amount of the chemical liquid can be reduced as compared with the case where the chemical liquid processing is performed while the substrate W is rotated by the second substrate processing portion 200k. The reason why the consumption amount of the chemical liquid can be reduced is that the first substrate processing portion 100n stores the chemical liquid (first processing liquid LQ1m) in the processing bath 103 to process the substrates W, and thus continuous discharge of the chemical liquid (second processing liquid LQ2q) as in the second substrate processing portion 200k is not required. The continuous discharge of the chemical liquid indicates that the chemical liquid is continuously discharged from the nozzle 217 of the second substrate processing portion 200k.

Preferably, in a case where chemical liquid processing is performed in a relatively short time or in a case where fine processing with the chemical liquid is performed, the second substrate processing portion 200k processes the substrate W while discharging the chemical liquid (second processing liquid LQ2q) from the nozzle 217. This is because the consumption amount of the chemical liquid is small in the chemical liquid processing for a relatively short time. In addition, since the second substrate processing portion 200k processes the substrate W with the chemical liquid discharged from the nozzle 217, it is possible to suppress the substrate W from being processed with the chemical liquid mixed with particles. Therefore, since the influence of particles can be reduced as much as possible, the second substrate processing portion 200k is suitable for the fine processing of the substrate W. In addition, the fact that the flow rate when the chemical liquid is discharged from the nozzle 217 can be adjusted is also the reason why the second substrate processing portion 200k is suitable for the fine processing of the substrate W.

In the first substrate processing portion 100n, since the substrates W are processed one by one, particles are not transferred between the substrates W during the processing. However, since the plurality of substrates W are processed one by one in the same processing bath 103, the possibility that past particles remain in the chemical liquid (first processing liquid LQ1m) in the processing bath 103 is not 0. However, even in this case, the number of remaining particles is significantly small as compared with a processing bath in which a plurality of substrates W are collectively processed. Therefore, in the first substrate processing portion 100n of the present preferred embodiment, the influence of particles can be significantly reduced.

As a result, preferably, the controller 4 (FIG. 1) controls the transfer mechanism 400 such that the substrate W for which a processing time exceeding a specified time T is set is carried into the first substrate processing portion 100n. Then, the controller 4 controls the first substrate processing portion 100n to process the carried-in substrate W with the first processing liquid LQ1m. As a result, the first substrate processing portion 100n processes the substrate W for which the processing time exceeding the specified time T is set with the first processing liquid LQ1m. Therefore, the consumption amount of the first processing liquid LQ1m can be reduced.

On the other hand, the controller 4 controls the transfer mechanism 400 such that the substrate W for which the processing time shorter than or equal to the specified time T is set is carried into the second substrate processing portion 200k. Then, the controller 4 controls the second substrate processing portion 200k to process the carried-in substrate W with the second processing liquid LQ2q. As a result, the second substrate processing portion 200k processes the substrate W for which the processing time shorter than or equal to the specified time T is set with the second processing liquid LQ2q. Therefore, the fine processing can be executed while suppressing the consumption amount of the second processing liquid LQ2q.

Also, in the present preferred embodiment, the first substrate processing portion 100n and the second substrate processing portion 200k adopt a configuration in which the substrates W are processed one by one. Therefore, as compared with a substrate processing apparatus including a processing bath in which a plurality of substrates W are collectively processed, the first substrate processing portion 100n and the second substrate processing portion 200k can be downsized, and the consumption amount of the chemical liquid can be reduced.

Furthermore, the substrate processing apparatus 1000 according to the present preferred embodiment includes not only the second substrate processing portion 200k that discharges the chemical liquid from the nozzle 217 to process the substrate W, but also the first substrate processing portion 100n that processes the substrate W with the chemical liquid stored in the processing bath 103. Therefore, as compared with a case where all the substrate processing portions of the substrate processing apparatus are configured by the second substrate processing portion 200k, the discharge capability of the chemical liquid by the processing liquid supplying unit 5m and the processing liquid supplying portion Aq can be lowered. As a result, the processing liquid supplying unit 5m and the processing liquid supplying portion Aq can be downsized. When all the substrate processing portions of the substrate processing apparatus are configured by the second substrate processing portion 200k, for example, in a case where all the second substrate processing portions 200k are used at the same time, there is a possibility that a relatively large discharge capability of the chemical liquid is required for the processing liquid supplying unit 5m and the processing liquid supplying portion Aq.

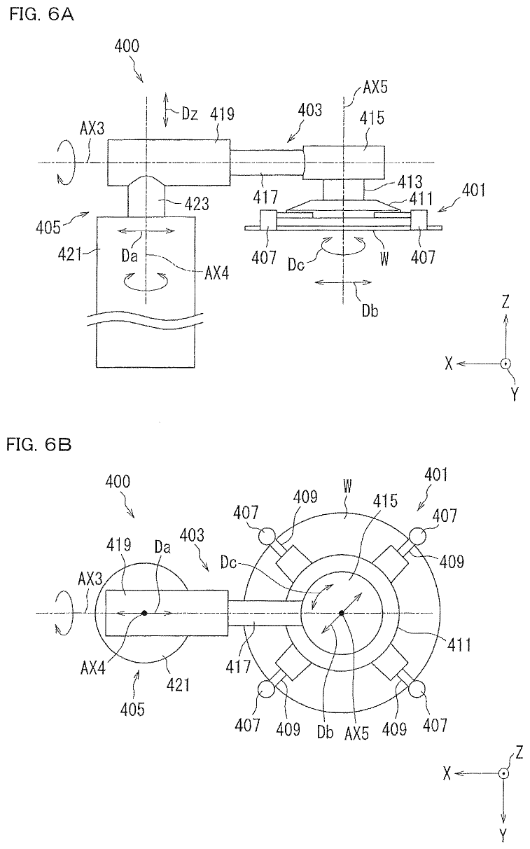

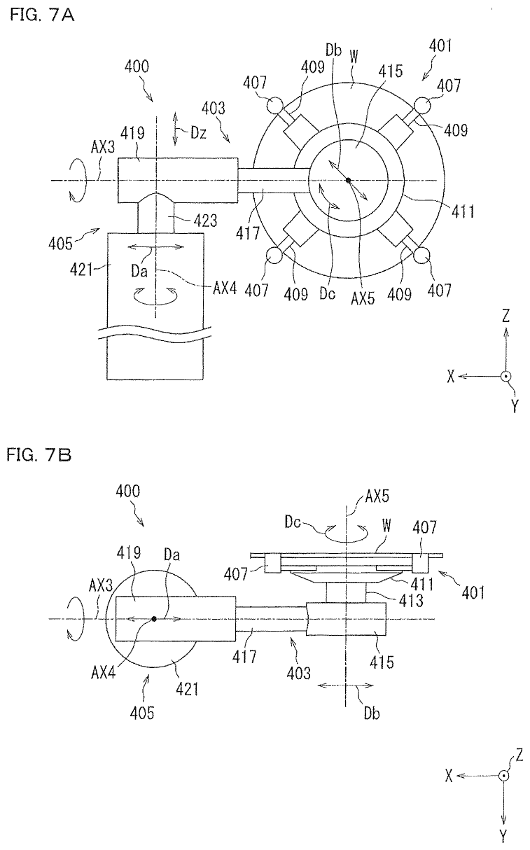

Next, details of the transfer mechanism 400 will be described with reference to FIGS. 6A, 6B, 7A, and 7B. FIG. 6A is a side view illustrating a state in which the transfer mechanism 400 holds the substrate W in the horizontal posture, and FIG. 6B is a plan view illustrating the state in which the transfer mechanism 400 holds the substrate W in the horizontal posture. FIG. 7A is a side view illustrating a state in which the transfer mechanism 400 holds the substrate W in the vertical posture, and FIG. 7B is a plan view illustrating the state in which the transfer mechanism 400 holds the substrate W in the vertical posture.

As illustrated in FIGS. 6A and 6B, the transfer mechanism 400 includes a hand portion 401, an arm portion 403, and a base portion 405. The hand portion 401 grips the substrate W. The arm portion 403 supports the hand portion 401. The arm portion 403 rotates the hand portion 401 around a rotational axis AX3. The rotational axis AX3 is substantially parallel to the horizontal direction. The base portion 405 supports the arm portion 403. The base portion 405 rotates the arm portion 403 around a rotational axis AX4. The rotational axis AX4 is substantially parallel to the vertical direction Dz. Therefore, when the arm portion 403 rotates around the rotational axis AX4, the hand portion 401 supported by the arm portion 403 rotates around the rotational axis AX4. In this case, the hand portion 401 rotates substantially horizontally. Furthermore, the base portion 405 raises or lowers the arm portion 403 along the vertical direction Dz. Therefore, when the arm portion 403 is raised or lowered, the hand portion 401 supported by the arm portion 403 is raised or lowered.

The arm portion 403 extends along a radial direction Da with respect to the rotational axis AX4. Then, the arm portion 403 expands and contracts along the radial direction Da. Therefore, the arm portion 403 can move the hand portion 401 outward in the radial direction Da or can move the hand portion 401 inward in the radial direction Da.

The radial direction Da is substantially orthogonal to the rotational axis AX4 and can take any direction of 360 degrees.

Specifically, the hand portion 401 includes a plurality of gripping members 407, a plurality of finger portions 409, a hand base portion 411, and a connection member 413. The arm portion 403 includes an arm base portion 419, an expansion/contraction portion 417, and a supporting portion 415. The base portion 405 includes a main body portion 421 and a shaft portion 423.

In the hand portion 401, the connection member 413 connects the hand base portion 411 to the arm portion 403. Specifically, the connection member 413 connects the hand base portion 411 to the supporting portion 415. The hand base portion 411 is a member expanding in a radial direction Db with respect to a center line AX5 of the hand base portion 411. The plurality of finger portions 409 are disposed at equal intervals along a circumferential direction Dc with respect to the center line AX5. The plurality of finger portions 409 extend from the hand base portion 411 along the radial direction Db. Each of the finger portions 409 can expand and contract along the radial direction Db. That is, the finger portion 409 can expand outward in the radial direction Db or can contract inward in the radial direction Db. For example, the finger portion 409 is driven by an air cylinder. The finger portion 409 is, for example, a substantially columnar member.

The gripping member 407 is fixed to a tip end portion of the finger portion 409 in the radial direction Db. Therefore, the plurality of gripping members 407 are disposed at equal intervals along the circumferential direction Dc. When the plurality of finger portions 409 expand outward in the radial direction Db, the plurality of gripping members 407 move outward in the radial direction Db. On the other hand, when the plurality of finger portions 409 contract inward in the radial direction Db, the plurality of gripping members 407 move inward in the radial direction Db.

Therefore, when the hand portion 401 grips the substrate W, the peripheral edge of the substrate W is gripped by the plurality of gripping members 407 by moving the plurality of gripping members 407 outward in the radial direction Db and then moving the plurality of gripping members 407 inward in the radial direction Db.

In the arm portion 403, the supporting portion 415 is connected to the hand base portion 411 by the connection member 413. Therefore, the supporting portion 415 supports the hand portion 401. The supporting portion portion 415 is attached to a tip end of the expansion/contraction portion 417 in the radial direction Da. The expansion/contraction portion 417 extends from the arm base portion 419 along the radial direction Da. The expansion/contraction portion 417 can expand and contract along the radial direction Da. That is, the expansion/contraction portion 417 can expand outward in the radial direction Da and can contract inward in the radial direction Da. For example, the expansion/contraction portion 417 is driven by an air cylinder.

The arm base portion 419 rotates the expansion/contraction portion 417 around the rotational axis AX3. As a result, the supporting portion 415 rotates around the rotational axis AX3, and the hand portion 401 rotates around the rotational axis AX3. The expansion/contraction portion 417 is, for example, a substantially columnar member. For example, the arm base portion 419 includes a motor, and the motor rotates the expansion/contraction portion 417 around the rotational axis AX3.

In the base portion 405, the shaft portion 423 extends from the main body portion 421 along the vertical direction Dz. The shaft portion 423 has, for example, a substantially columnar shape. The shaft portion 423 is connected to the arm base portion 419. Specifically, an upper end portion of the shaft portion 423 is connected to the arm base portion 419. Therefore, the shaft portion 423 supports the arm base portion 419. The main body portion 421 raises or lowers the shaft portion 423. As a result, the arm base portion 419 is raised or lowered. Therefore, the expansion/contraction portion 417 and the supporting portion 415 are raised or lowered, and the hand portion 401 is raised or lowered. The main body portion 421 includes, for example, a ball screw mechanism and a motor that applies a driving force to the ball screw mechanism in order to raise and lower the shaft portion 423.

The main body portion 421 rotates the shaft portion 423 around the rotational axis AX4. As a result, the arm base portion 419 rotates around the rotational axis AX4. Therefore, the expansion/contraction portion 417 and the supporting portion 415 rotate around the rotational axis AX4, and the hand portion 401 rotates around the rotational axis AX4. For example, the main body portion 421 includes a motor, and the motor rotates the shaft portion 423 around the rotational axis AX4.

As illustrated in FIGS. 6A and 6B, the hand portion 401 grips the substrate W in the horizontal posture. Specifically, the hand portion 401 holds the substrate W in the horizontal posture in which the substrate W faces downward.

Then, when the arm portion 403 rotates the hand portion 401 gripping the substrate W in the horizontal posture by approximately 90 degrees around the rotational axis AX3, the hand portion 401 grips the substrate W in the vertical posture as illustrated in FIGS. 7A and 7B.

When the arm portion 403 rotates the hand portion 401 gripping the substrate W in the vertical posture by approximately 90 degrees around the rotational axis AX3, the hand portion 401 grips the substrate W in the horizontal posture as illustrated in FIGS. 6A and 6B.

In the present preferred embodiment, gripping the substrate W by the hand portion 401 is synonymous with holding the substrate W by the hand portion 401. The arm portion 403 can grip the substrate W in the horizontal posture in which the substrate W faces upward.

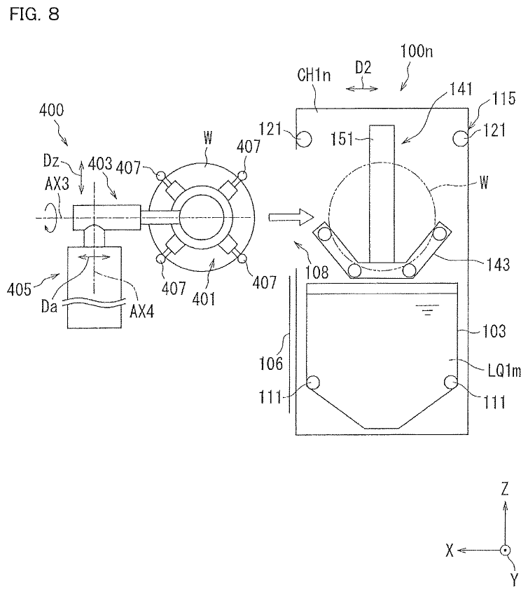

Next, the carry-in of the substrate W from the transfer mechanism 400 into the first substrate processing portion 100n will be described with reference to FIGS. 6A to 8. FIG. 8 is a view illustrating a state in which the transfer mechanism 400 delivers the substrate W to the first substrate processing portion 100n.

As illustrated in FIGS. 6A and 6B, the transfer mechanism 400 receives the substrate W in the horizontal posture. Then, as illustrated in FIGS. 7A and 7B, the transfer mechanism 400 changes a posture of the substrate W from the horizontal posture to the vertical posture.

Further, as illustrated in FIG. 8, the transfer mechanism 400 carries the substrate W in the vertical posture into the first substrate processing portion 100n. Specifically, first, the shutter 106 opens the opening 108 of the first chamber CH1n. Next, the arm portion 403 expands outward in the radial direction Da. Then, the hand portion 401 gripping the substrate W in the vertical posture enters the first chamber CH1n through the opening 108. Then, the hand portion 401 delivers the substrate W in the vertical posture to the substrate holding portion 143 standing by in the first chamber CH1n. Then, the substrate holding portion 143 holds the substrate W in the vertical posture. In this way, the transfer mechanism 400 carries the substrate W in the vertical posture into the first substrate processing portion 100n.

For example, when the hand portion 401 is caused to enter the first chamber CH1n, the transfer mechanism 400 causes the hand portion 401 to enter the first chamber CH1n from a position where the hand portion 401 is shifted in the first direction D1 (FIG. 1) with respect to the substrate holding portion 143. Thereafter, the transfer mechanism 400 moves the hand portion 401 in the first direction D1 such that the hand portion 401 approaches the substrate holding portion 143, and delivers the substrate W to the substrate holding portion 143. With such an operation, when the hand portion 401 is caused to enter the first chamber CH1n, the hand portion 401 can be prevented from coming into contact with the substrate holding portion 143 in the radial direction Da (second direction D2).

The transfer mechanism 400 moves in the first direction D1 (FIG. 1) to move the hand portion 401 in the first direction D1.

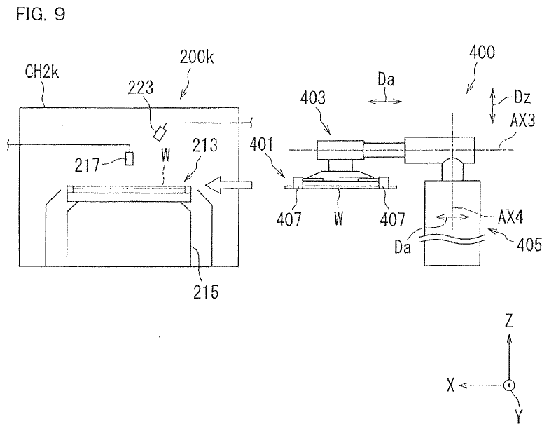

Next, the carry-in of the substrate W from the transfer mechanism 400 into the second substrate processing portion 200k will be described with reference to FIG. 9. FIG. 9 is a view illustrating a state in which the transfer mechanism 400 delivers the substrate W to the second substrate processing portion 200k. Further, as illustrated in FIG. 9, the transfer mechanism 400 carries the substrate W in the horizontal posture into the second substrate processing portion 200k.

Specifically, first, a shutter (not illustrated) opens an opening (not illustrated) of a side wall of the second chamber CH2k. Next, the arm portion 403 expands outward in the radial direction Da. Then, the hand portion 401 gripping the substrate W in the horizontal posture enters the second chamber CH2k through the opening (not illustrated). Then, the hand portion 401 delivers the substrate W in the horizontal posture to the spin chuck 213 standing by in the second chamber CH2k. Then, the spin chuck 213 holds the substrate W in the horizontal posture. In this way, the transfer mechanism 400 carries the substrate W in the horizontal posture into the second substrate processing portion 200k.

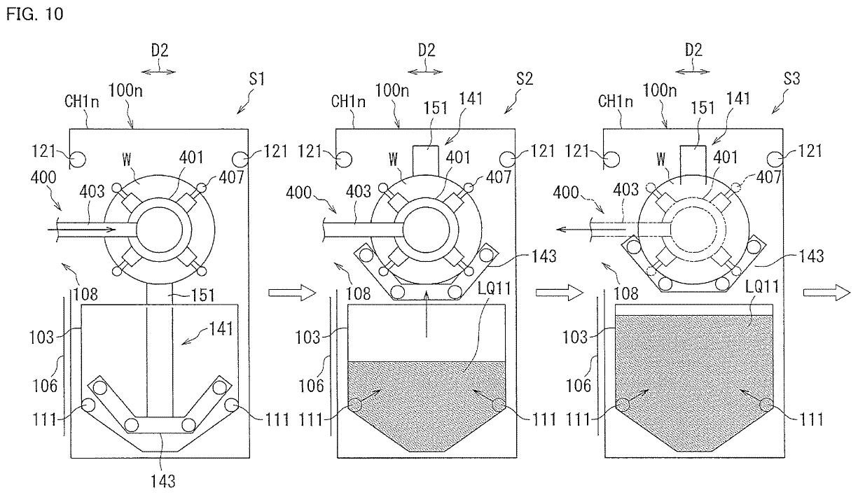

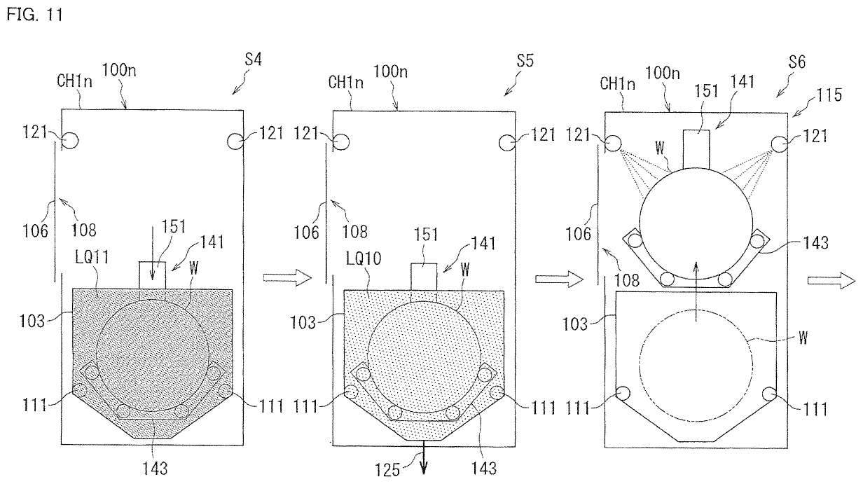

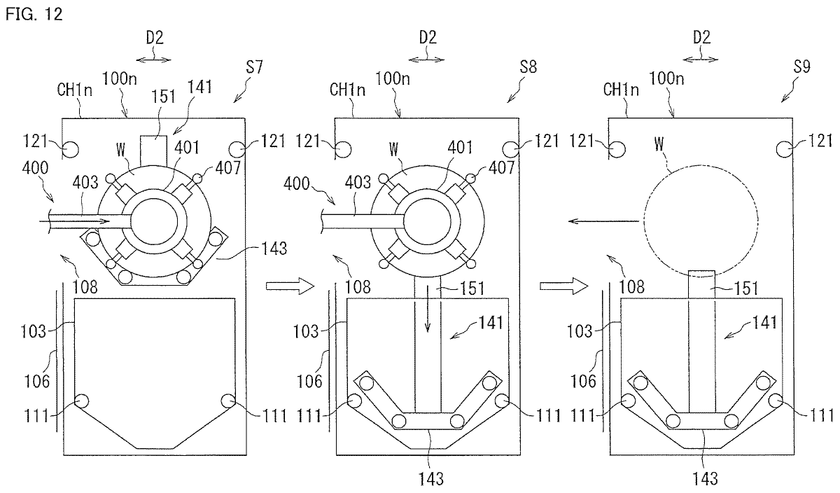

Next, an example of a substrate processing method showing a procedure from the carry-in of the substrate W into the first substrate processing portion 100n to the carry-out of the substrate W through processing will be described with reference to FIGS. 10 to 12. FIGS. 10 to 12 are views illustrating an example of the substrate processing method. FIG. 10 illustrates the carry-in of the substrate W. FIG. 11 illustrates immersion of the substrate W. FIG. 12 shows the carry-out of the substrate W. The substrate processing method is executed by the substrate processing apparatus 1000. Specifically, the controller 4 controls the first substrate processing portion 100n, the second substrate processing portion 200k, and the transfer mechanism 400 to execute the substrate processing method. As illustrated in FIGS. 10 to 12, the substrate processing method includes step S1 to step S9. Steps S1 to S9 are executed by the same first substrate processing portion 100n (for example, a first substrate processing portion 1001).

First, in step S1, the shutter 106 opens the opening 108. Then, the arm portion 403 of the transfer mechanism 400 expands in the second direction D, and allows the hand portion 401 gripping the substrate W in the vertical posture to enter the first chamber CH1n through the opening 108. As a result, the substrate W is carried-in from the first substrate processing portion 100n. In this case, the substrate placement mechanism 141 causes the substrate holding portion 143 to stand by in the processing bath 103. That is, the substrate holding portion 143 stands by at an inside-bath position. In step S1, as an example, the first processing liquid LQ11 is not stored in the processing bath 103.

Next, in step S2, the substrate placement mechanism 141 raises the substrate holding portion 143 from the processing bath 103 to the outside-bath position, and causes the substrate holding portion 143 to receive the substrate W in the vertical posture from the hand portion 401. The nozzle 111 supplies the first processing liquid LQ11 to the processing bath 103. The first processing liquid LQ11 is a chemical liquid.

Next, in step S3, the arm portion 403 of the transfer mechanism 400 contracts in the second direction D2, and retracts the hand portion 401 from the inside of the first chamber CH1n to the outside of the first chamber CH1n through the opening 108. After the retraction of the hand portion 401, the shutter 106 closes the opening 108. In step S3, the first processing liquid LQ11 is stored in the processing bath 103. In addition, the substrate holding portion 143 that has received the substrate W in the vertical posture stands by at an outside-bath position over the processing bath 103.

Next, as illustrated in FIG. 11, in step S4, the substrate placement mechanism 141 immerses the substrate W in the first processing liquid LQ11 by lowering the substrate holding portion 143 holding the substrate W in the vertical posture from the outside-bath position into the processing bath 103. As a result, the substrate W is processed with the first processing liquid LQ11. In this case, the substrate holding portion 143 is disposed at the inside-bath position.

Next, in step S5, the draining portion 125 and the nozzle 111 replace the first processing liquid LQ11 in the processing bath 103 with the first processing liquid LQ10. In this case, the draining portion 125 discharges the first processing liquid LQ11 to the outside of the processing bath 103, and the nozzle 111 supplies the first processing liquid LQ10 into the processing bath 103. The first processing liquid LQ10 is a rinse liquid. Therefore, the substrate W held by the substrate holding portion 143 is cleaned with the first processing liquid LQ10. After cleaning the substrate W with the first processing liquid LQ10, the draining portion 125 discharges the first processing liquid LQ10 to the outside of the processing bath 103.

Next, in step S6, the substrate placement mechanism 141 pulls up the substrate W from the inside of the processing bath 103 by raising the substrate holding portion 143 holding the substrate W in the vertical posture from the inside of the processing bath 103 to the outside-bath position. Then, the nozzle 121 supplies vapor of an organic solvent (for example, IPA) having a smaller surface tension than that of the first processing liquid LQ10 (rinse liquid) into the first chamber CH1n in which the pulled-up substrate W is present. As a result, the first processing liquid LQ10 adhering to the substrate W is replaced with the organic solvent, and drying of the substrate W is promoted while collapse of a structure constituting the pattern of the substrate W is suppressed. Thus, in step S6, the substrate W is dried in the first chamber CH1n. In step S6, as an example, the processing bath 103 is empty.

Preferably, the nozzle 121 supplies the vapor of the organic solvent into the first chamber CH1n, and then supplies an inert gas into the first chamber CH1n. As a result, drying of the substrate W can be further promoted. More preferably, the substrate W is dried in a state where the pressure in the first chamber CH1n is reduced by the decompression portion 131 (FIG. 2). This is because drying of the substrate W can be further promoted. For example, in a state where the pressure in the first chamber CH1n is reduced, the nozzle 121 supplies the vapor of the organic solvent into the first chamber CH1n. For example, in a state where the pressure in the first chamber CH1n is reduced, the nozzle 121 supplies the inert gas into the first chamber CH1n.

Next, as illustrated in FIG. 12, in step S7, the shutter 106 opens the opening 108. In this case, the substrate holding portion 143 holds the dried substrate W and stands by at an outside-bath position of the first chamber CH1n. Then, the arm portion 403 of the transfer mechanism 400 expands in the second direction D, and allows the hand portion 401 to enter the first chamber CH1n through the opening 108.

Next, in step S8, the hand portion 401 receives the dried substrate W from the substrate holding portion 143. Then, the substrate placement mechanism 141 lowers the substrate holding portion 143 from the outside-bath position into the processing bath 103. As a result, the substrate holding portion 143 is disposed at the inside-bath position.

Next, in step S9, the arm portion 403 of the transfer mechanism 400 contracts in the second direction D2, and retracts the hand portion 401 gripping the dried substrate W in the vertical posture from the inside of the first chamber CH1n to the outside of the first chamber CH1n through the opening 108. As a result, the substrate W is carried out from the first substrate processing portion 100n. After the retraction of the hand portion 401, the shutter 106 closes the opening 108. Then, the substrate processing method ends.

Next, another example of the substrate processing method according to the present preferred embodiment will be described with reference to FIGS. 1, 2, 8, 9, 13, and 14. The substrate processing method is executed by the substrate processing apparatus 1000. Specifically, the controller 4 controls the first substrate processing portion 100n, the second substrate processing portion 200k, and the transfer mechanism 400 to execute the substrate processing method.

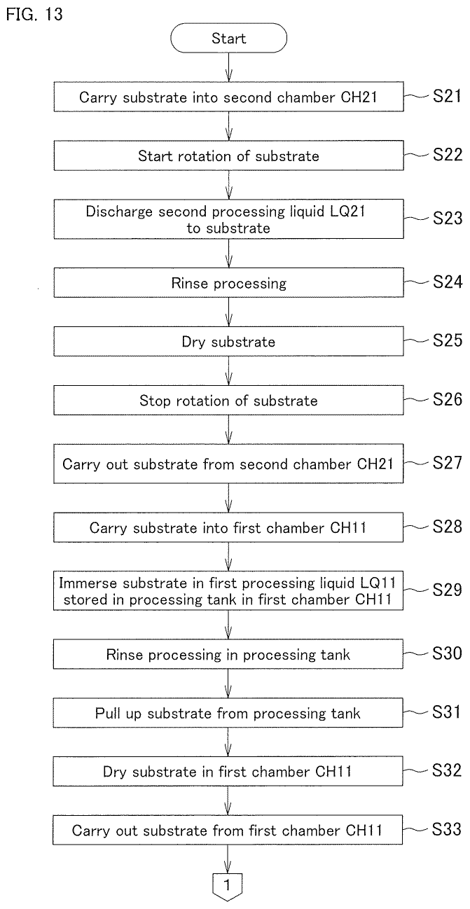

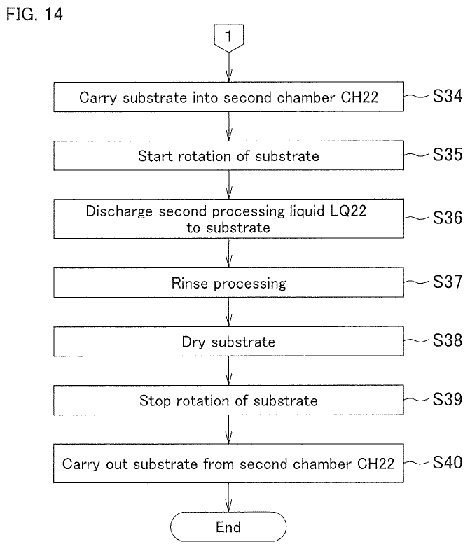

In the substrate processing method described with reference to FIGS. 13 and 14, as an example, the first substrate processing portion 1001 (first chamber CH11) among the plurality of first substrate processing portions 100n in FIG. 1 is used. That is, n=1. As an example, the second substrate processing portion 2001 (second chamber CH21) and the second substrate processing portion 2002 (second chamber CH22) among the plurality of second substrate processing portions 200k in FIG. 1 are used. That is, k=1, 2.

FIGS. 13 and 14 are flowcharts illustrating another example of the substrate processing method. As illustrated in FIGS. 13 and 14, the substrate processing method includes step S21 to step S40.

First, as shown in FIGS. 9 and 13, in step S21, the transfer mechanism 400 carries one substrate W in the horizontal posture into the second chamber CH21 (k=1 in FIG. 9) of the second substrate processing portion 2001 (k=1 in FIG. 9).

Next, in step S22, the spin motor 215 starts rotation of the substrate W by rotating the spin chuck 213.

Next, in step S23, the nozzle 217 discharges the second processing liquid LQ21 (q=1 in FIG. 5) to the substrate W. The second processing liquid LQ21 is a chemical liquid. Therefore, the substrate W is processed with the second processing liquid LQ21. The chemical liquid is, for example, hydrofluoric acid. In this case, for example, an oxide film formed on the substrate W is removed with hydrofluoric acid. The nozzle 217 stops discharging the second processing liquid LQ21 after a first predetermined time.

Next, in step S24, the nozzle 223 discharges the second processing liquid LQ20 (q=0 in FIG. 5) to the substrate W. The second processing liquid LQ20 is a rinse liquid. Therefore, the substrate W is cleaned with the second processing liquid LQ20. The nozzle 223 stops discharging the second processing liquid LQ20 after a second predetermined time.

Next, in step S25, the substrate W is dried by rotation of the spin chuck 213 by the spin motor 215.

Next, in step S26, the spin motor 215 stops rotation of the substrate W by stopping the rotation of the spin chuck 213.

Next, in step S27, the transfer mechanism 400 carries out one substrate W in the horizontal posture from the second chamber CH21.

Next, as shown in FIGS. 8 and 13, in step S28, the transfer mechanism 400 changes a posture of one substrate W from the horizontal posture to the vertical posture, and carries one substrate W into the first chamber CH11 (n=1 in FIG. 8) of the first substrate processing portion 1001 (n=1 in FIG. 8). In this case, the hand portion 401 of the transfer mechanism 400 delivers the substrate W in the vertical posture to the substrate holding portion 143 of the first substrate processing portion 1001.

Next, in step S29, the substrate placement mechanism 141 immerses the substrate W in the first processing liquid LQ11 (m=1 in FIG. 8) in the processing bath 103 by lowering the substrate holding portion 143 holding one substrate W in the vertical posture. The first processing liquid LQ11 is a chemical liquid. Therefore, the substrate W is processed with the first processing liquid LQ11. The chemical liquid is, for example, phosphoric acid. In this case, for example, a nitride film formed on the substrate W is etched with phosphoric acid. In step S29, the substrates W are processed with the first processing liquid LQ11 in the processing bath 103 for a third predetermined time.

Next, in step S30, the draining portion 125 (FIG. 2) discharges the first processing liquid LQ11 from the processing bath 103, and the nozzle 111 supplies the first processing liquid LQ10 (m=0 in FIG. 8) to the processing bath 103. As a result, the first processing liquid LQ11 is replaced with the first processing liquid LQ10. Then, the processing bath 103 cleans the substrate W with the rinse liquid which is the first processing liquid LQ10.

Next, in step S31, the substrate placement mechanism 141 pulls up the substrate W from the processing bath 103 by raising the substrate holding portion 143 holding one substrate W in the vertical posture.

Next, in step S32, the drying portion 115 dries the substrate W in the first chamber CH11.

Next, in step S33, the transfer mechanism 400 carries out one substrate W in the vertical posture from the first chamber CH11.

Next, as shown in FIGS. 9 and 14, in step S34, the transfer mechanism 400 changes a posture of one substrate W from the vertical posture to the horizontal posture, and carries one substrate W into the second chamber CH22 (k=2 in FIG. 9) of the second substrate processing portion 2002 (k=2 in FIG. 9). In this case, the hand portion 401 of the transfer mechanism 400 delivers the substrate W in the horizontal posture to the spin chuck 213 of the second substrate processing portion 2002.

Next, in step S35, the spin motor 215 starts rotation of the substrate W by rotating the spin chuck 213.

Next, in step S36, the nozzle 217 discharges the second processing liquid LQ22 (q=2 in FIG. 5) to the substrate W. The second processing liquid LQ22 is a chemical liquid. Therefore, the substrate W is processed with the second processing liquid LQ22. The chemical liquid is, for example, SC1. In this case, for example, the organic substance adhering to the substrate W is removed. The nozzle 217 stops discharging the second processing liquid LQ22 after a fourth predetermined time.

Next, in step S37, the nozzle 223 discharges the second processing liquid LQ20 (q=0 in FIG. 5) to the substrate W. The second processing liquid LQ20 is a rinse liquid. Therefore, the substrate W is cleaned with the second processing liquid LQ20. The nozzle 223 stops discharging the second processing liquid LQ20 after a fifth predetermined time.

Next, in step S38, the substrate W is dried by rotation of the spin chuck 213 by the spin motor 215.

Next, in step S39, the spin motor 215 stops rotation of the substrate W by stopping the rotation of the spin chuck 213.

Next, in step S40, the transfer mechanism 400 carries out one substrate W in the horizontal posture from the second chamber CH22. Then, the substrate processing method ends.

As described above, in the substrate processing method described with reference to FIGS. 13 and 14, the processing time (third predetermined time) with the first processing liquid LQ11 (chemical liquid) in the first chamber CH11 is longer than the processing time (first predetermined time) with the second processing liquid LQ21 (chemical liquid) in the second chamber CH21, and longer than the processing time (fourth predetermined time) with the second processing liquid LQ22 (chemical liquid) in the second chamber CH22. Therefore, according to the present preferred embodiment, the consumption amount of the chemical liquid can be reduced as compared with the case where the processing with the same chemical liquid as the first processing liquid LQ11 (chemical liquid) is executed in the second chamber CH2k. This is because the substrate W is processed with the chemical liquid stored in the processing bath 103 instead of continuing the discharge of the chemical liquid in the processing bath 103 of the first chamber CH11.

The preferred embodiments (including modified examples) of the present invention have been described above with reference to the drawings. However, the present invention is not limited to the preferred embodiments described above and can be implemented in various modes within a scope not deviating from its gist. Also, it is possible to modify, as appropriate, the plurality of constituent elements disclosed in the preferred embodiments described above. For example, a certain constituent element among all constituent elements of a certain preferred embodiment may be added to the constituent elements of another preferred embodiment or some constituent elements among all constituent elements of a certain preferred embodiment may be deleted from the preferred embodiment.

Further, the drawings mainly illustrate the respective constituent elements schematically to facilitate understanding of the invention and there are cases where thicknesses, lengths, numbers, intervals, etc., of the respective constituent elements illustrated differ from actuality due to convenience of drawing preparation. Also, the arrangements of the respective constituent elements indicated in the preferred embodiments described above are but an example, are not restricted in particular, and can obviously be changed variously within a scope of practically not deviating from the effects of the present invention.

(1) In the substrate processing apparatus 1000 illustrated in FIG. 1, the controller 4 may cause the transfer mechanism 400 to transfer the substrate W, thereby causing two or more different first substrate processing portions 100n to sequentially execute a plurality of processes determined in order.

Further, in the substrate processing apparatus 1000, the controller 4 may cause the transfer mechanism 400 to transfer the substrate W, thereby causing two or more different second substrate processing portions 200k to sequentially execute a plurality of processes determined in order.

Furthermore, in the substrate processing apparatus 1000, the controller 4 may cause the transfer mechanism 400 to transfer the substrate W, thereby causing one or more first substrate processing portions 100n and one or more second substrate processing portions 200k to sequentially execute a plurality of processes determined in order. In this case, the plurality of processings can be optimally distributed to the first substrate processing portions 100n and the second substrate processing portions 200k by utilizing the characteristics of the first substrate processing portion 100n (for example, which are effective for long-time processing) and the characteristics of the second substrate processing portion 200k (for example, which are effective for short-time processing or fine processing).

(2) In FIG. 1, the substrate processing apparatus 1000 may include a plurality of transfer mechanisms 400.

The present invention relates to a substrate processing apparatus and has industrial applicability.

What is claimed is:

1. A substrate processing apparatus comprising:
a first substrate processing portion that processes substrates one by one by immersing each of the substrates in a vertical posture in a first processing liquid; and
a transfer mechanism that receives the substrate in a horizontal posture, changes a posture of the substrate from the horizontal posture to the vertical posture, and carries the substrate in the vertical posture into the first substrate processing portion,
wherein the first substrate processing portion includes
a processing bath which has a capacity corresponding to a single substrate, in which only the single substrate in the vertical posture is disposed, and in which the first processing liquid is stored, and
a substrate placement mechanism that receives the single substrate from the transfer mechanism and places only the single substrate in the vertical posture in the first processing liquid.

2. The substrate processing apparatus according to claim 1, wherein the first substrate processing portion further includes
a chamber that accommodates the processing bath, and
a drying portion that dries the substrate raised from the processing bath in the chamber.

3. The substrate processing apparatus according to claim 1, wherein a plurality of the first substrate processing portions are provided,
the plurality of first substrate processing portions are disposed along a first direction substantially parallel to a horizontal direction, and
the transfer mechanism carries the substrate in the vertical posture into each of the plurality of first substrate processing portions by moving on a transfer passage extending along the first direction.

4. The substrate processing apparatus according to claim 3, further comprising a plurality of second substrate processing portions disposed along the first direction,
wherein each of the plurality of second substrate processing portions processes the substrates one by one by discharging a second processing liquid to the rotating substrate in the horizontal posture,
the transfer mechanism carries the substrate in the horizontal posture into each of the plurality of second substrate processing portions by moving on the transfer passage,
the plurality of first substrate processing portions are disposed on one side of the transfer passage in a second direction,
the plurality of second substrate processing portions are disposed on the other side of the transfer passage in the second direction, and
the second direction is substantially orthogonal to the first direction.

5. The substrate processing apparatus according to claim 4, further comprising a controller that controls the transfer mechanism, the first substrate processing portion, and the second substrate processing portion,
wherein the controller causes the transfer mechanism to transfer the substrate such that one or more of the first substrate processing portions and one or more of the second substrate processing portions execute a plurality of processes having order in accordance with the order.

6. The substrate processing apparatus according to claim 1, further comprising:
a second substrate processing portion that processes the substrates one by one by discharging a second processing liquid to the rotating substrate in the horizontal posture; and
a controller that controls the transfer mechanism,
wherein the controller
controls the transfer mechanism such that the substrate for which a processing time exceeding a specified time is set is carried into the first substrate processing portion, and
controls the transfer mechanism such that the substrate for which a processing time shorter than or equal to the specified time is set is carried into the second substrate processing portion.
